(19) United States
(12) Patent Application Publication
(10) Pub. No.: US 2024/0336031 A1
(43) Pub. Date: Oct. 10, 2024

(54) WINDOW MEMBER AND MANUFACTURING METHOD THEREOF

(71) Applicant: SAMSUNG DISPLAY CO., LTD., YONGIN-SI (KR)

(72) Inventor: EUNJOO LEE, YONGIN-SI (KR)

(21) Appl. No.: 18/413,347

(22) Filed: Jan. 16, 2024

(30) Foreign Application Priority Data
Apr. 7, 2023 (KR) 10-2023-0046075

(51) Int. Cl. B32B 7/12; B32B 3/26; B32B 17/06; B32B 27/06; B32B 37/12; H10K 59/80

(52) U.S. Cl. CPC B32B 7/12; B32B 3/266; B32B 17/06; B32B 27/06; B32B 37/12; H10K 59/873; B32B 2255/26; B32B 2310/0831; B32B 2457/20

(57) ABSTRACT

A window member according to an embodiment includes a cover window including a hole area; and a protective film disposed on a surface of the cover window and including an adhesive layer on a surface facing the cover window. The adhesive layer includes a cured portion overlapping the hole area and having no adhesiveness.

### CROSS-REFERENCE TO RELATED APPLICATION

This application claims priority under 35 U.S.C. § 119 to Korean Patent Application No. 10-2023-0046075, filed on Apr. 7, 2023, in the Korean Intellectual Property Office, and all the benefits accruing therefrom, the entire contents of which are incorporated herein by reference.

### BACKGROUND

### (a) Technical Field

This disclosure relates to a window member and a manufacturing method thereof. More specifically, it relates to a window member including a cover window and a protective film protecting the cover window, and a manufacturing method thereof.

### (b) Description of the Related Art

A display device is a device that displays images, which can include a liquid crystal display (LCD), an organic light emitting diode (OLED), a quantum dot light emitting diode (QLED), a micro LED, etc. These display devices are used in various electronic devices, such as mobile phones, navigational devices, digital cameras, electronic books, portable game machines, and various terminals.

The display device may include a display panel that utilizes a screen for displaying the image and a cover window to protect the display panel from external impact and other damage. The cover window can have a protective film attached during handling to prevent surface contamination and damage during processing. This protective film may be removed before a bonding process between the cover window and the display panel.

The window member may include the cover window and the protective film attached to a surface of the cover window for protection. The protective film may include a base layer and an adhesive layer on one side of the base layer. The protective film may be attached to the cover window by this adhesive layer. When the adhesive layer of the protective film touches a specific area on the cover window surface, it may act as a foreign particle. In addition, problems such as adhesive material remaining on the surface of the cover window after the protective film is removed may occur.

### SUMMARY

Embodiments of the inventive concept relate to providing a window member including a protective film from which an adhesive force is removed in a specific area.

Embodiments relate to a method of manufacturing a window member and the window member manufactured thereby, where contamination of the cover window by the remaining adhesive material of the protective film can be prevented.

A window member according to an embodiment includes a cover window including a hole area; and a protective film disposed on a surface of the cover window, wherein the protective film includes an adhesive layer on a surface facing the cover window. The adhesive layer includes a cured portion overlapping the hole area and lacking an adhesiveness.

The protective film may further include a base layer, and the adhesive layer may be between the base layer and the cover window.

A thickness of the adhesive layer may be less than a thickness of the base layer.

The cured portion may be an area having an adhesive force of 0 gram-force (gf).

An area of the cured portion may be equal to or greater than an area of the hole area.

The adhesive layer may include at least one of a acrylic adhesive, a silicone adhesive, or a urethane adhesive.

The hole area may include an opening exposing the cover window and a light blocking layer surrounding the opening.

The light blocking layer may be disposed between the cover window and the adhesive layer.

The light blocking layer may be in contact with the cured portion.

A distance between the cover window and the protective film in the hole area may be determined by a thickness of the light blocking layer.

A manufacturing method of a window member according to an embodiment includes preparing a protective film having an adhesive layer formed on a surface thereof; positioning a jig including a jig hole to face the protective film; forming a cured portion corresponding to the jig hole in the adhesive layer by irradiating UV light through the jig hole; and attaching the protective film to a surface of a cover window.

The cover window may include a hole area on the surface, and the jig hole may correspond to a planar shape of the hole area.

The attaching of the protective film to the surface of the cover window may include attaching the protective film to the surface of the cover window such that the cured portion of the protective film overlaps the hole area.

An area of the cured portion may be equal to or greater than an area of the hole area.

The protective film may further include a base layer in contact with the adhesive layer, and a thickness of the adhesive layer may be less than a thickness of the base layer.

The cured portion may be an area where an adhesive force is 0 gf.

The adhesive layer may include at least one of an acrylic adhesive, a silicone adhesive, or a urethane adhesive.

The cover window may further include a light blocking layer defining the hole area.

The light blocking layer may be in contact with the cured portion.

A distance between the cover window and the protective film in the hole area may be determined by a thickness of the light blocking layer.

According to the embodiments, the window member including the protective film from which an adhesive force is removed in a specific area corresponding to the hole area of the cover window may be provided. Accordingly, it is possible to prevent problems due to a contact or residue of an adhesive material on the surface of the cover window.

In addition, the window member including the protective film from which an adhesive force is removed in a specific area may be provided without using an additional member such as a masking tape. Accordingly, problems caused by the use of the masking tape, for example, defects such as detachment of the masking tape or folding of the masking tape toward the cover window may be prevented.

In addition, since an additional member such as a masking tape is not used, it is possible to reduce a step between the cover window and the protective film in a specific area of the cover window. Accordingly, it is possible to reduce defects by minimizing the reaction between the adhesive component of the adhesive layer and an air layer in the area where the step occurs.

### BRIEF DESCRIPTION OF THE DRAWINGS

FIG. 1 is an exploded perspective view showing schematically a display device, according to an embodiment.

FIG. 2 is a partial rear view of a cover window, according to an embodiment.

FIG. 3 is a cross-sectional view of a window member, according to an embodiment.

FIG. 4 is a rear view of a window member, according to an embodiment.

FIG. 5 is a cross-sectional view according to an embodiment taken along B-B′ in

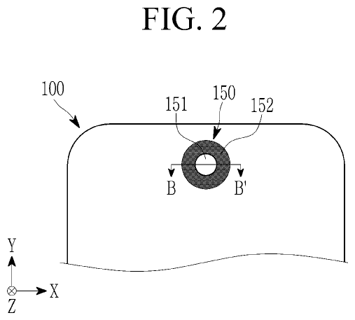

FIG. 2.

FIG. 6 is a flowchart of a manufacturing method of a window member, according to an embodiment.

FIG. 7 is a schematic top plan view explaining a manufacturing method of a window member, according to an embodiment.

FIG. 8 and FIG. 9 are schematic cross-sectional views describing a manufacturing method of a window member, according to an embodiment.

FIG. 10 is a cross-sectional view, according to a comparative example taken along A-A′ in FIG. 2.

FIG. 11 is a cross-sectional view, according to an embodiment along A-A′ in FIG. 2.

FIG. 12 is a cross-sectional view schematically showing a stacked structure of a display panel, according to an embodiment.

### DETAILED DESCRIPTION

The features of the various embodiments of this disclosure are described more fully hereinafter with reference to the accompanying drawings, in which embodiments are shown. As those skilled in the art would realize, the embodiments may be modified in various different ways without departing from the spirit or scope of this disclosure.

Parts that are not connected with the description may be omitted, whereas the same elements or equivalents are referred to by the same reference numerals throughout the specification.

In addition, because sizes and thicknesses of constituent members shown in the accompanying drawings are depicted in a manner for better understanding and ease of description, the embodiments are not limited to those shown. In the drawings, for example, the thickness of layers, films, panels, components, areas, etc., may be exaggerated, and the thicknesses of some layers and areas may be enlarged for clarity.

It will be understood that when an element such as a layer, film, area, or substrate is referred to as being “on” another element, it can be directly on the other element or intervening elements may also be present. In contrast, when an element is referred to as being “directly on” another element, there are no intervening elements present. Further, in the specification, the word “on” or “above” can include being positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side, as illustrated.

In the drawings, symbols “X”, “Y”, and “Z” representing directions are used, where “X” is a first direction, “Y” is a second direction perpendicular to the first direction, and “Z” is a third direction perpendicular to the first direction and the second direction. Also, to overlap two constituent elements means that two constituent elements are overlapped in the third direction DR3 (e.g., a direction perpendicular to an upper surface of the substrate) unless stated otherwise. The directions indicated by the first to third directions X, Y, and Z are relative concepts and may be converted into other directions.

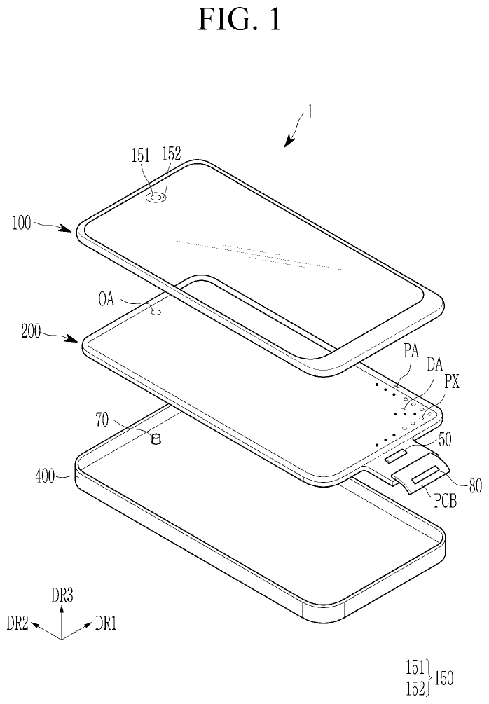

FIG. 1 is a schematic exploded perspective view of a display device, according to an embodiment.

Referring to FIG. 1, a display device 1 may display an image toward a third direction Z on a plane defined by a first direction X and a second direction Y. The front (or top) and back (or bottom) faces of each member in the embodiment are defined by the third direction Z. The normal direction of each of the front and rear surfaces may be parallel to the third direction Z.

In various embodiments, the display device 1 may display a motion image (e.g., video) or a still image. A display device 1 according to an embodiment is a device for displaying a motion picture or a still image, and may be used as a display screen of various products such as a television, a laptop, a monitor, an advertisement board, as a component in the Internet of things (IoT), etc., as well as portable electronic devices such as a mobile phone, a smart phone, a tablet personal computer, a mobile communication terminal, an electronic notebook, an e-book, a portable multimedia player (PMP), a navigation device, an Ultra Mobile PC (UMPC), etc. In addition, the display device 1 according to an embodiment may be used in a wearable device, such as a smart watch, a watch phone, a glasses display, and a head mounted display (HMD). FIG. 1 illustrates the display device 1 as a smartphone for better comprehension and ease of description.

A display device 1 according to an embodiment may include a cover window 100, a display panel 200, a component 70, and a housing member 400.

In various embodiments, the cover window 100 may be configured to overlap the display panel 200 and cover the front of the display panel 200. The cover window 100 can be disposed on the upper part of the display panel 200 to protect the display panel 200, while transmitting light emitted from the display panel 200.

In various embodiments, the cover window 100 is made of a transparent material, including, but not limited to, glass and/or plastic. For example, the cover window 100 may include ultra thin glass (UTG) with a thickness of about 0.1 mm or less, polyimide (PI), polyethylene terephthalate (PET), and polycarbonate (PC), and the like.

In various embodiments, the cover window 100 may include a hole area 150, where the hole area 150 may include an opening 151 through which one surface of the cover window 100 is exposed and a light blocking layer 152 surrounding the opening. The opening 151 may be an optically transparent area and may transmit incident light. The light blocking layer 152 may be an area having relatively low light transmittance compared to the opening 151, where the incident light can be attenuated. The light blocking layer 152 may define the shape of the opening 151.

The hole area 150 may overlap with a component 70, where the component 70 may be a light emitting module, a light sensing module, or a photographing module. The component 70 may operate by receiving an external signal provided through the hole area 150, where the external signal can be a light signal. The hole area 150 may have a circular shape on a plane, where the size and/or shape may be variously modified. The position and number of the hole area 150 may be changed.

In various embodiments, the display panel 200 may be a flat rigid display panel or a flexible display panel. The display panel according to an embodiment may be a light emitting display panel, where the display panel may be, for example, an organic light emitting panel or a quantum dot light emitting display panel.

The display panel 200 may include a display area DA and a peripheral area PA. The display area DA is an area where an image is displayed and may correspond to a screen. The peripheral area PA is an area in which an image is not displayed and may surround at least a part of the display area DA. The display area DA may have a substantially rectangular shape on a plane. The display area DA may have a polygon shape, such as a triangle, pentagon, or hexagon, a circular shape, an elliptical shape, or an irregular shape.

In various embodiments, a plurality of pixels PX are arranged in the display area DA of the display panel 200, and an image may be displayed by light emission from a combination of the pixels PX. The display panel 200 may include pixel circuits and signal lines for driving the pixels PX. The display panel 200 may be a light emitting display panel including light-emitting elements, where each light-emitting element may constitute a pixel PX.

The display panel 200 according to an embodiment may include an opening area OA penetrating the display panel 200. The opening area OA may overlap the hole area 150 of the cover window 100. The opening area OA may be positioned in the display area DA, where the opening area OA may be positioned in the upper center of the display area DA. The opening area OA may also be positioned at other locations within the display area DA, such as the upper left side of the display area DA or the upper right side of the display area DA. The opening area OA may have a circular shape on a plane, and the size and/or shape may be variously modified. The position and number of the opening area OA may be variously changed.

In various embodiments, the display panel 200 includes the peripheral area PA extending from the display area DA, and on which a plurality of signal lines and a pad portion are positioned. A data driver 50 may be positioned on the peripheral area PA, and the pad portion of the peripheral area PA may be electrically connected to a printed circuit board (PCB) including a driving chip 80.

A component 70 for adding various functions to the display device 1 may be positioned corresponding to the opening area OA, where the component 70 can be aligned with the opening area OA extending through the thickness of the display panel 200. The component 70 may be electrically connected to the display panel 200 through an electrical connector or the like. The component 70 may be at least one of a light emitting module, a light sensing module, or a photographing module (e.g., camera). For example, the component 70 may include at least one of a light emitting module that outputs infrared rays, a CMOS sensor for detecting infrared rays, or a camera module that captures an image of an external subject. An image of a subject received through the hole area 150 and opening area OA may be photographed. The component 70 may be composed of a single module or may include a plurality of modules, where the module or modules may be arranged in various sizes and/or position relationships.

In various embodiments, the housing member 400 is disposed on the lower side of the display panel 200. The housing member 400 can be combined with the cover window 100 to form the exterior of the display device 1. The housing member 400 may include a material with relatively high rigidity, where for example, the housing member 400 may include a plurality of frames and/or plates made of glass, plastic, and metal. The display panel 200 and the component 70 may be positioned in an interior space of the display device 1 formed by the cover window 100 and the housing member 400. The display panel 200 may be accommodated within the internal space and protected from external impact by the walls and surfaces of the cover window 100 and the housing member 400.

FIG. 2 is a partial rear view of a cover window, according to an embodiment.

When the cover window 100 is mounted on the display device 1, the rear surface of the cover window 100 becomes the surface facing the display panel 200, and the front surface of the cover window 100 becomes the surface from which an image on the screen is projected.

Referring to FIG. 2, the cover window 100 may include the hole area 150 on the rear surface. The hole area 150 may include an opening 151 exposing the cover window 100 and a light blocking layer 152 surrounding the opening 151. The light blocking layer 152 may be formed of a material capable of reflecting, absorbing, or otherwise blocking incident light. For example, dark color pigments, such as black pigment or gray pigment, dark color dyes, metals, such as aluminum or silver, metal oxides, and dark color polymers may be used, as the light blocking material. The light blocking layer 152 may be formed as a printed pattern of the light blocking material surrounding the opening 151. The printing pattern may be formed of an ink composition including a dye or pigment by methods such as screen printing, inkjet printing, gravure printing, offset printing, etc.

In various embodiments, a protective film 300 for protecting the cover window 100 may be attached to the rear surface of the cover window 100. The protective film 300 and the cover window 100 may be attached by an adhesive layer 320 of the protective film 300, where the rear surface of the cover window 100 may come into contact with the adhesive layer 320 of the protective film 300. Accordingly, a defect in which the adhesive material of the adhesive layer 320 is smeared in the hole area 150 of the cover window 100 may occur.

In order to prevent adhesive material from being introduced into the hole area 150, when the protective film 300 is attached, a transfer of the adhesive component to the area corresponding to the hole area 150 may be prevented by using a non-adhesive masking tape or the like. However, when such a masking tape is used, a level difference between the cover window 100 and the protective film 300 increases depending on the thickness of the masking tape separating the surface of the cover window 100 from the adhesive layer 320 of the protective film 300, and a lifting phenomenon may occur. In addition, the adhesive component may be transferred to the hole area 150 of the cover window 100 while the masking tape is separated or partially folded toward the cover window 100. The case of using such a masking tape is further explained through a comparative example of FIG. 10.

In various embodiments, the protective film 300 may be configured to prevent the adhesive component of the protective film 300 from being transferred to the hole area 150 of the cover window 100 without using a masking tape.

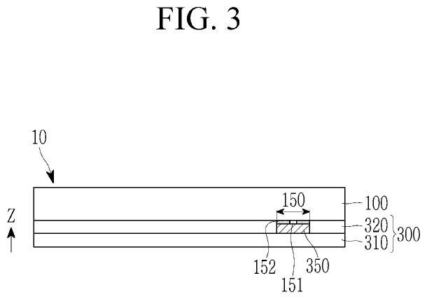

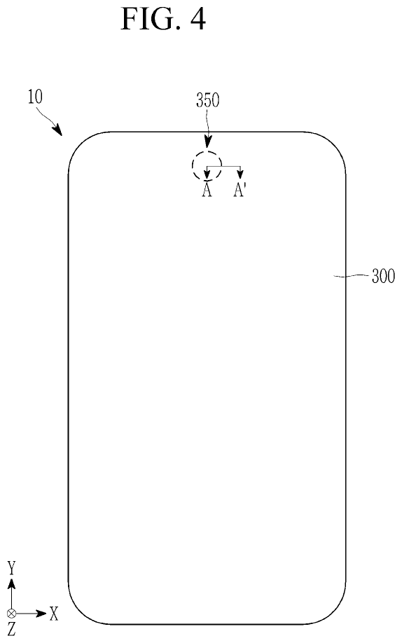

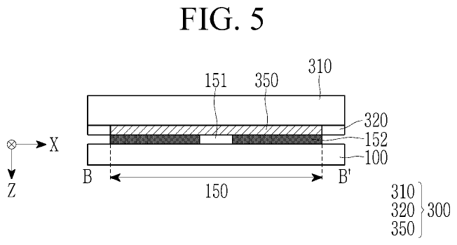

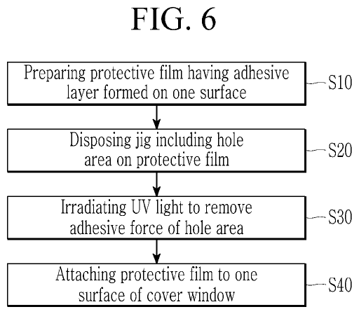

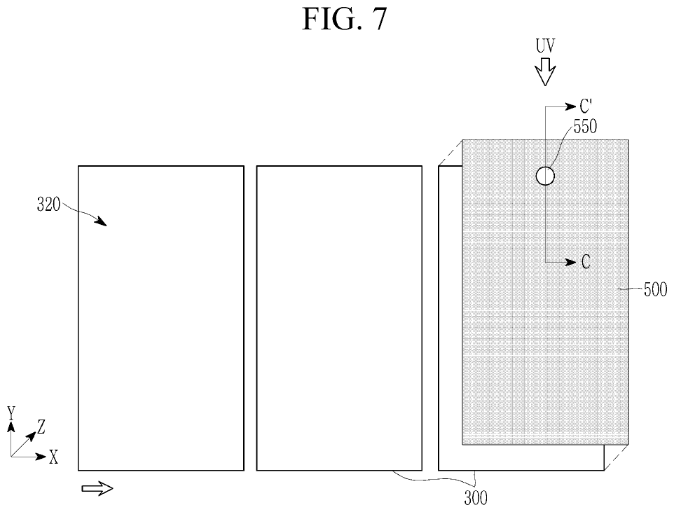

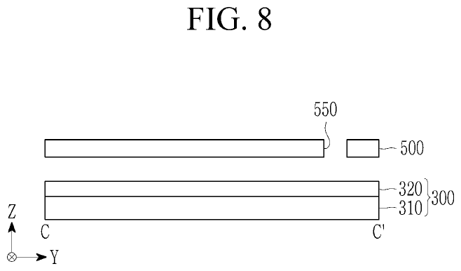

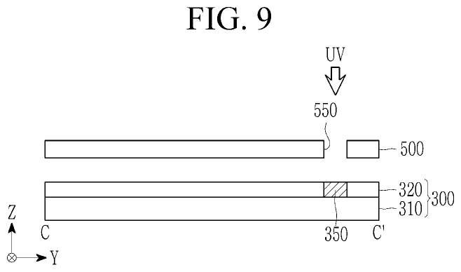

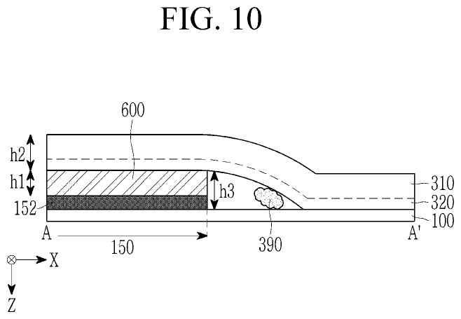

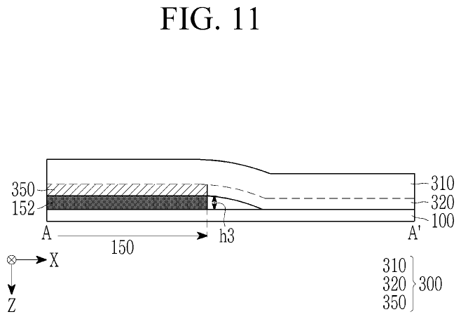

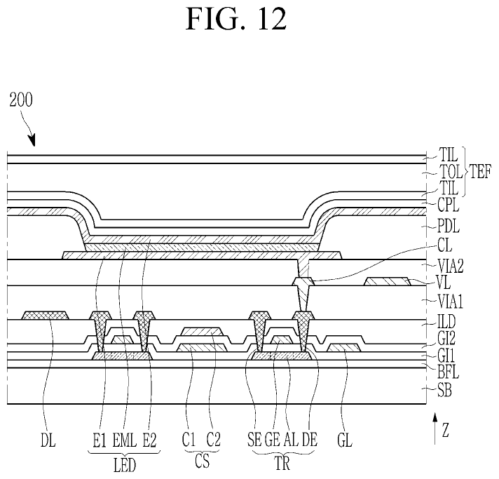

FIG. 3 is a cross-sectional view of a window member, according to an embodiment. FIG. 4 is a rear view of a window member, according to an embodiment. FIG. 5 is a cross-sectional view taken along B-B′ in FIG. 2.

Referring to FIG. 3 to FIG. 5, the window member 10 may include a cover window 100 and a protective film 300 positioned on one surface of the cover window 100, where the protective film 300 can be positioned on the rear surface of the cover window 100. The rear surface of the cover window 100 may be covered by the protective film 300.

In various embodiments, the protective film 300 is attached to the cover window 100 to protect the cover window 100, while the cover window 100 is transported and loaded, but is peeled off and removed when the cover window 100 is mounted on the display panel 200 or a touch member. The overall planar shape of the protective film 300 may conform to and be the same as the planar shape of the cover window 100.

The protective film 300 may include a base layer 310 and an adhesive layer 320. The protective film 300 may include an adhesive layer 320 on the surface of the base layer 310 facing the cover window 100, and the protective film 300 may be attached to the rear surface of the cover window 100 by the adhesive layer 320. The adhesive layer 320 can be between the base layer 310 and the cover window 100. A thickness of the adhesive layer 320 may be less than a thickness of the base layer 310.

In various embodiments, the base layer 310 of the protective film 300 may include a polymer, such as polyethylene terephthalate (PET), poly (methyl methacrylate) (PMMA), polycarbonate (PC), triacetyl cellulose (TAC), and cycloolefin polymer (COP).

The adhesive layer 320 may include an adhesive such as acryl adhesive, silicone adhesive, and urethane adhesive. The base layer 310 and the adhesive layer 320 may each be transparent.

The adhesive layer 320 of the protective film 300 may be formed thinner than the base layer 310. For example, the base layer 310 may have a thickness of about 30 μm to about 60 μm, and the adhesive layer 320 may have a thickness of about 10 μm to about 30 μm.

The adhesive layer 320 may include an ultraviolet (UV) adhesive (a light cure adhesive) that is cured by irradiation with ultraviolet (UV) rays. The UV adhesive reacts with a photoinitiator included in a liquid adhesive by ultraviolet rays, and a hardening (curing) may occur in a solid state. The area when the hardening occurs is cured in a solid state and has no adhesive force. The adhesive layer may include the cured portion, which overlaps the hole area and lacks adhesiveness, for example, the adhesive force of the adhesive layer 320 may be about 2 gram-force (gf) to about 8 gf, whereas the adhesive force of the cured area may be 0 gf.

The protective film 300 according to an embodiment may be integrally provided with an adhesive layer 320 formed on one surface of the base layer 310, where the adhesive layer 320 can be coextensive with the base layer 310. The adhesive layer 320 may be disposed between the cover window 100 and the base layer 310 to attach the protective film 300 to the cover window 100. The adhesive layer 320 may include a cured portion 350 (or hardened portion) overlapping the hole area 150 of the cover window 100. The cured portion 350 may refer to an area where the adhesive layer 320 is irradiated with UV light and the adhesive layer 320 having a viscosity is cured to become a solid state, where the adhesive layer 320 can transition from a liquid to solid state. The cured portion 350 may lose the adhesive property, and be an area having an adhesive force of 0 gram-force (gf), so does not have an adhesiveness. Since the cured portion 350 does not have the adhesive property, it is possible to prevent the adhesive material from being smeared in the hole area 150 of the display panel 200.

The cured portion 350 of the protective film 300 may have a planar shape corresponding to the hole area 150 of the cover window 100, where the cured portion 350 can overlap the hole area 150. The cured portion 350 may be larger than the hole area 150, where an area of the cured portion may be equal to or greater than an area of the hole area 150. One or more cured portions 350 may be provided in the adhesive layer 320. The size, shape, placement, etc. of the cured portion 350 may be changed according to the various embodiments.

FIG. 5 is a schematic cross-sectional view of a window member according to an embodiment taken along B-B′ in FIG. 2.

In various embodiments, the cover window 100 may include a hole area 150 on the rear surface (the lower surface based on the Z direction). The hole area 150 may include an opening 151 exposing the rear surface of the cover window 100 and a light blocking layer 152 positioned surrounding the opening 151 and blocking an external light. The light blocking layer 152 can prevent light incident from the outside from moving into the display panel 200, where the light blocking layer 152 may be a printing pattern formed of a dark color ink. In an embodiment, the hole area 150 may be defined along the outer boundary of the light blocking layer 152.

In various embodiments, the protective film 300 is disposed on the rear surface of the cover window 100. The protective film 300 may include a base layer 310 and an adhesive layer 320 positioned on one surface of the base layer 310. The adhesive layer 320 may include a cured portion 350 corresponding to the hole area 150 of the cover window 100. The cured portion 350 may be the same size and shape as the hole area 150 or may have a larger area that can cover the hole area 150 to provide a positioning tolerance, where the cured portion 350 can be aligned with the hole area 150. For example, the entire hole area 150 may be positioned within the cured portion 350. The cured portion 350 may be a non-adhesive area having an adhesive force of 0 gf. The cured portion 350 may be an area where the adhesive layer 320 is solidified and cured by UV irradiation, such that the cured portion 350 has lost its adhesive properties.

When the protective film 300 is attached to the cover window 100, the cured portion 350 of the protective film 300 may overlap the hole area 150 of the cover window 100. Because the cured portion 350 does not have an adhesive property, the transfer of the adhesive component of the adhesive layer 320 to the hole area 150 may be prevented. In addition, because the protective film 300 does not include a separate masking tape, the lifting of the protective film 300, when attached to the cover window 100, may be reduced or avoided, and process defects that occur when the masking tape is used may be reduced or avoided. FIG. 6 is a flowchart of a manufacturing method of a window member, according to an embodiment. FIG. 7 is a schematic top plan view explaining a manufacturing method of a window member, according to an embodiment. FIG. 8 and FIG. 9 are schematic cross-sectional views explaining a manufacturing method of a window member, according to an embodiment.

A manufacturing method of a window member according to an embodiment is described through FIG. 6 to FIG. 9. A window member may include a cover window and a protective film on one surface of the cover window.

Referring to FIG. 6, a protective film 300 with an adhesive layer 320 formed on a side of the protective film 300 is prepared (S10). Subsequently, a jig including a jig hole is disposed on the upper side of the protective film (S20). The jig hole of the jig may correspond to the hole area 150 of the cover window 100. Thereafter, the jig hole is irradiated with UV light to remove the adhesive force in a predetermined area of the protective film corresponding to the jig hole (S30). The adhesive layer of the protective film includes a viscous liquid adhesive material, which is converted into a solid by the UV irradiation, thereby forming a cured portion from which the viscosity and adhesive properties are removed. Then, the protective film is attached to the rear surface of the cover window so that the adhesive layer of the protective film is positioned to face the rear surface of the cover window, and the cured portion of the protective film overlaps the hole area of the cover window (S40).

Referring to FIG. 7, a plurality of protective films 300 are placed in adjacent positions. The protective film 300 may include an adhesive layer 320 on one surface, where the protective film 300 may be oriented so that the adhesive layer 320 faces upward. A jig 500 may be positioned on the protective film 300. The jig 500 may have a shape corresponding to the shape of the protective film 300 and may include a jig hole 550 penetrating the jig 500. UV light may be used to irradiate the protective film 300 through the jig hole 550 of the jig 500, where the jig 500 can block the UV light from regions of the protective film 300 outside the jig hole 550. The adhesive layer 320 of the protective film 300 may be cured by the UV irradiation. Accordingly, the adhesive layer 320 of the protective film 300 is cured in a predetermined area corresponding to the jig hole 550, and an adhesive force of the adhesive layer 320 may be removed. The cured portion 350 of the protective film 300 may be provided to correspond to the hole area 150 of the cover window 100, where the location of the jig hole 550 can coincide with the location of the hole area 150. The jig hole 550 of the jig 500 may have a planar shape corresponding to the hole area 150 of the cover window 100, and the size, number, shape, location, etc. of the jig hole 550 may be variously changed according to the embodiment.

In various embodiments, the plurality of protective films 300 can each move along a first direction (X), where the protective films 300 can be positioned below the jig 500. When the protective film 300 is positioned below the jig 500 and aligned for UV irradiation, UV light is irradiated through the jig hole 550 of the jig 500. Accordingly, the adhesive layer 320 of the protective film 300 exposed to the UV irradiation becomes cured. A cured portion 350, referring to FIG. 9, corresponding to the jig hole 550 may be formed in the adhesive layer 320.

FIG. 8 is a cross-sectional view taken along C-C′ of FIG. 7, which is a cross-sectional view when the protective film is aligned with the jig and positioned.

In various embodiments, the protective film 300 includes a base layer 310 and an adhesive layer 320 on the base layer 310. The adhesive layer 320 of the protective film 300 is oriented to face the jig 500. The jig 500 may include a jig hole 550, and the jig hole 550 extends through the jig 500.

Subsequently, as shown in FIG. 9, UV light may be irradiated from the upper side of the jig 500. UV light is light having a wavelength band of about 100 nm to about 410 nm, and for example, UV light of a wavelength band of 340 nm to 405 nm may be irradiated. UV light may pass through the jig hole 550 of the jig 500 and irradiate the adhesive layer 320 of the protective film 300. Accordingly, the cured portion 350 from which the adhesive force is removed may be formed on the adhesive layer 320. The cured portion 350 may be formed in a shape corresponding to the jig hole 550.

In a non-limiting example, the adhesive layer 320 may have a thickness of approximately 20 μm and may include an acryl adhesive. When the adhesive layer 320 is irradiated with UV light at an intensity of 500 mW/cm² or more for about 120 seconds or more, the adhesive layer 320 is cured into a solid state, and adhesive properties may be removed. In the cured state, the adhesive force of the adhesive layer 320 may be 0 gf.

Subsequently, a protective film 300 may be attached to the rear surface of the cover window 100. The rear surface of the cover window 100 and the adhesive layer 320 of the protective film 300 may be attached to face each other. On the rear surface of the cover window 100, the hole area 150 and the cured portion 350 of the protective film 300 may overlap. Since the hole area 150 overlaps with the cured portion 350 having no adhesive force, the adhesive component of the adhesive layer 320 is not transferred to the hole area 150, thereby reducing defects.

FIG. 10 is a cross-sectional view, according to a comparative example taken along A-A′ in FIG. 4. FIG. 11 is a cross-sectional view, according to an embodiment along A-A′ in FIG. 4.

FIG. 10 is a comparative example in which a non-adhesive masking tape 600 is disposed in a predetermined area corresponding to a hole area 150 of a cover window 100 in order to prevent the transfer of the adhesive component of the protective film to the hole area of the cover window. The non-adhesive masking tape 600 can separate the cover window 100 from the adhesive layer 320 of the protective film 300, and form a gap adjacent to the non-adhesive masking tape 600.

Referring to FIG. 10, a light blocking layer 152 is positioned on the rear surface of the cover window 100. The light blocking layer 152 may include a light absorbing material. The light blocking layer 152 may be a printing pattern including dark color ink.

A masking tape 600 may be positioned on the light blocking layer 152. The masking tape 600 may be a non-adhesive material. One surface of the masking tape 600 may be in contact with the light blocking layer 152. The masking tape 600 may have a first thickness h1. For example, the first thickness h1 of the masking tape 600 may range from about 20 μm to about 30 μm, where for example, the masking tape 600 may have a thickness of 25 μm.

A protective film 300 may be positioned on the masking tape 600. The other surface of the masking tape 600 may contact the adhesive layer 320 of the protective film 300. The protective film 300 may cover the masking tape 600 and the cover window 100. The protective film 300 may have a second thickness h2. The second thickness h2 of the for example protective film 300 may be approximately 70 μm.

Referring to FIG. 10, a gap having a height h3 equal to the thickness of the light blocking layer 152 and the masking tape 600 may occur between the protective film 300 and the cover window 100 around the hole area 150 of the cover window 100. A certain space is formed by the gap with height h3 between the protective film 300 and the cover window 100, and accordingly, moisture in an air layer may react with the adhesive layer 320 to form a solidified material 390. Accordingly, for example, circular stains may occur in the periphery of the hole area 150 of the cover window 100.

FIG. 11 is an embodiment in which the protective film 300 including the cured portion 350 is attached to the cover window 100.

In an embodiment, the protective film 300 may include a cured portion 350 in which the adhesive layer 320 is cured by UV light. The cured portion 350 is an area from which adhesive force is removed, and may be formed to correspond to the hole area 150 of the cover window 100. Accordingly, since a separate masking tape 600 covering the hole area 150 is not used, the height of the gap h3 between the protective film 300 and the cover window 100 may be reduced.

In various embodiments, the distance h3 between the protective film 300 and the cover window 100 around the hole area 150 may be reduced by the thickness h1 of the masking tape 600. Accordingly, the cover window 100 and the protective film 300 may come into closer contact, minimize the height h3 around the hole area 150, and reduce or prevent defects caused by a reaction between moisture in the air and the adhesive layer. The distance h3 between the cover window 100 and the protective film 300 in the hole area 150 can be determined by the thickness of the light blocking layer 152.

In addition, since the protective film 300 according to an embodiment does not attach a separate masking tape 600, process defects such as folding, misplacement, or separation of the masking tape 600 may be prevented. In addition, because masking tape 600 is not used, there is an effect of reducing a process cost.

FIG. 12 is a cross-sectional view schematically showing a stacked structure of a display panel 200, according to an embodiment.

In various embodiments, a display panel 200 may include a substrate SB, a transistor TR formed on the substrate SB, and a displaying layer including a light-emitting element LED connected to the transistor TR.

The substrate SB may be a flexible substrate including a polymer resin, such as polyimide, polyamide, or polyethylene terephthalate.

A buffer layer BFL may be positioned on the substrate SB. The buffer layer BFL may improve the characteristics of the semiconductor layer by blocking impurities from the substrate SB during the formation of the semiconductor layer, and the buffer layer BFL may alleviate the stress of the semiconductor layer by flattening the surface of the substrate SB.

On the buffer layer BFL, a semiconductor layer AL of the transistor TR may be positioned. The semiconductor layer AL may include a first area, a second area, and a channel area between the first area and second area. The semiconductor layer AL may include amorphous silicon, polysilicon, and/or an oxide semiconductor.

A first gate insulating layer GI1 may be positioned on the semiconductor layer AL. The first gate insulating layer GI1 may include an inorganic insulating material such as silicon nitride, silicon oxide, and silicon oxynitride.

On the first gate insulating layer GI1, a first gate conductive layer that may include a gate electrode GE of the transistor TR, a gate line GL, and a first electrode C1 of a capacitor CS may be positioned. The first gate conductive layer may include molybdenum (Mo), aluminum (Al), copper (Cu), titanium (Ti), or the like.

A second gate insulating layer GI2 may be positioned on the first gate conductive layer. The second gate insulating layer GI2 may include an inorganic insulating material, such as silicon nitride, silicon oxide, and/or silicon oxynitride.

A second gate conductive layer that may include a second electrode C2 of a capacitor CS may be positioned on the second gate insulating layer GI2. The second gate conductive layer may include molybdenum (Mo), aluminum (Al), copper (Cu), titanium (Ti), or the like.

An interlayer insulating layer ILD may be positioned on the second gate insulating layer GI2 and the second gate conductive layer. The interlayer insulating layer ILD may include an inorganic insulating material such as silicon nitride, silicon oxide, and silicon oxynitride.

On the interlayer insulating layer ILD, a first data conductive layer that may include a first electrode SE and a second electrode DE of the transistor TR, a data line DL, etc. may be positioned. The first electrode SE and the second electrode DE may be respectively electrically connected to the first and second areas of the semiconductor layer AL through contact holes of the insulating layers GI1, GI2, and ILD. One of first electrode SE and second electrode DE may be a source electrode and the other may be a drain electrode. The first and second areas of the semiconductor layer AL may be electrically connected to the channel area of the semiconductor layer AL.

A first planarization layer VIA1 may be positioned on the first data conductive layer. The first planarization layer VIA1 may be an organic insulator.

A second data conductive layer, which may include a voltage line VL, a connection layer CL, and the like, may be positioned on the first planarization layer VIA1. The voltage line VL may transmit voltages such as a driving voltage, a common voltage, an initialization voltage, and a reference voltage. The connection layer CL may be electrically connected to the second electrode DE of the transistor TR through a contact hole of the first planarization layer VIA1.

In various embodiments, the first and second data conductive layers may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and the like.

A second planarization layer VIA2 may be positioned on the second data conductive layer. The second planarization layer VIA2 may be an organic insulator.

A first electrode E1 of a light-emitting element LED may be positioned on the second planarization layer VIA2. The first electrode E1 may be referred to as a pixel electrode. The first electrode E1 may be electrically connected to the connection layer CL through the contact hole of the second planarization layer VIA2. Therefore, the first electrode E1 is electrically connected to the second electrode DE of the transistor TR and may receive a data signal that controls a luminance of the light-emitting element LED. The transistor TR to which the first electrode E1 is connected may be a driving transistor or a transistor electrically connected to the driving transistor. The first electrode E1 may be formed of a reflective conductive material or a semi-transmissive conductive material, or may be formed of a transparent conductive material.

A pixel definition layer PDL, which may be an organic insulator, may be positioned on the second planarization layer VIA2. The pixel definition layer PDL may be referred to as a barrier rib and may have an opening overlapping the first electrode E1.

Above the first electrode E1, an emission layer EML of the light-emitting element LED may be positioned. On the first electrode E1, in addition to the emission layer EML, at least one of a hole injection layer, a hole transport layer, an electron transport layer and an electron injection layer may be positioned.

On the emission layer EML, a second electrode E2 of the light-emitting element LED may be positioned. The second electrode E2 may be referred to as a common electrode. The second electrode E2 may be made of a metal or metal alloy with low work function, such as calcium (Ca), barium (Ba), magnesium (Mg), aluminum (Al), silver (Ag), etc., where the second electrode E2 may be a sufficiently thin layer to allow light transmission. The second electrode E2 may include a transparent conductive oxide such as indium tin oxide (ITO) or indium zinc oxide (IZO).

The first electrode E1, the emission layer EML, and the second electrode E2 of each pixel form a light-emitting element LED like an organic light emitting element. The first electrode E1 may be an anode of a light-emitting element, and the second electrode E2 may be a cathode of a light-emitting element.

Above the second electrode E2, a capping layer CPL may be positioned. The capping layer CPL may increase an optical efficiency of the light-emitting element by adjusting the refractive index. The capping layer CPL may be positioned to entirely cover the second electrode E2. The capping layer CPL may include an organic insulating material or an inorganic insulating material.

An encapsulation layer TEF may be positioned on the capping layer CPL. The encapsulation layer TEF may encapsulate the light-emitting element LED and prevent the penetration of moisture and/or oxygen from the outside. The encapsulation layer TEF may be a thin film encapsulation layer including at least one inorganic layer TIL and at least one organic layer TOL.

While this disclosure has been described in connection with what is presently considered to be practical embodiments, it is to be understood that the inventive concept is not limited to the disclosed embodiments. On the contrary, it is intended to cover various modifications and equivalent arrangements included within the spirit and scope of the appended claims.

What is claimed is:

1. A window member comprising:
a cover window including a hole area; and
a protective film disposed on a surface of the cover window, wherein the protective film includes an adhesive layer on a surface facing the cover window, and
wherein the adhesive layer includes a cured portion, which overlaps the hole area and lacks adhesiveness.

2. The window member of claim 1, wherein:
the protective film further includes a base layer, and
the adhesive layer is between the base layer and the cover window.

3. The window member of claim 2, wherein:
a thickness of the adhesive layer is less than a thickness of the base layer.

4. The window member of claim 1, wherein:
the cured portion is an area having an adhesive force of 0 gram-force (gf).

5. The window member of claim 1, wherein:
an area of the cured portion is equal to or greater than an area of the hole area.

6. The window member of claim 1, wherein:
the adhesive layer includes at least one of an acrylic adhesive, a silicone adhesive, or a urethane adhesive.

7. The window member of claim 1, wherein:
the hole area includes an opening exposing the cover window and a light blocking layer surrounding the opening.

8. The window member of claim 7, wherein:
the light blocking layer is between the cover window and the adhesive layer.

9. The window member of claim 8, wherein:
the light blocking layer is in contact with the cured portion.

10. The window member of claim 8, wherein:
a distance between the cover window and the protective film in the hole area is determined by a thickness of the light blocking layer.

11. A manufacturing method of a window member comprising:
preparing a protective film having an adhesive layer formed on a surface thereof;
positioning a jig including a jig hole to face the protective film;
forming a cured portion corresponding to the jig hole in the adhesive layer by irradiating UV light through the jig hole; and
attaching the protective film to a surface of a cover window.

12. The manufacturing method of the window member of claim 11, wherein:
the cover window includes a hole area on the surface, and
the jig hole corresponds to a planar shape of the hole area.

13. The manufacturing method of the window member of claim 12, wherein:
the attaching of the protective film to the surface of the cover window includes
attaching the protective film to the surface of the cover window, wherein the cured portion of the protective film overlaps the hole area.

14. The manufacturing method of the window member of claim 12, wherein:
an area of the cured portion is equal to or greater than an area of the hole area.

15. The manufacturing method of the window member of claim 11, wherein:
the protective film further includes a base layer in contact with the adhesive layer, and
a thickness of the adhesive layer is less than a thickness of the base layer.

16. The manufacturing method of the window member of claim 11, wherein:
the cured portion is an area where an adhesive force is 0 gf.

17. The manufacturing method of the window member of claim 11, wherein:
the adhesive layer includes at least one of an acrylic adhesive, a silicone adhesive, or a urethane adhesive.

18. The manufacturing method of the window member of claim 12, wherein:
the cover window further includes a light blocking layer defining the hole area.

19. The manufacturing method of the window member of claim 18, wherein:
the light blocking layer is in contact with the cured portion.

20. The manufacturing method of the window member of claim 18, wherein:
a distance between the cover window and the protective film in the hole arca is determined by a thickness of the light blocking layer.
